(19) United States
(12) Patent Application Publication
(10) Pub. No.: US 2008/0054267 A1
(43) Pub. Date: Mar. 6, 2008

(54) DISPLAY APPARATUS AND MANUFACTURING METHOD OF THE SAME

(75) Inventor: Takuji IMAMURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/847,873

(22) Filed: Aug. 30, 2007

(30) Foreign Application Priority Data
Sep. 4, 2006 (JP) 2006-238500

(51) Int. Cl. H01L 21/00; H01L 29/786

(52) U.S. Cl. 257/72; 438/34; 257/E33.001; 257/E29.273

(57) ABSTRACT

A display apparatus includes a silicon oxide film and a silicon nitride film as a base layer placed on an insulating substrate, a polycrystalline silicon electrode placed on the base layer, a gate insulating film placed on the polycrystalline silicon electrode, and a gate metal electrode placed on the gate insulating film at a position opposite to the polycrystalline silicon electrode. The gate metal electrode partly or entirely covers the edge of the polycrystalline silicon electrode when viewed from the top.

### BACKGROUND OF THE INVENTION

1. Field of the Invention

The present invention relates to an active matrix display apparatus where thin film transistors are arranged in an array, and a manufacturing method of the same. Particularly, the present invention relates to a capacitor which is formed in the same step as thin film transistors for driving pixels in a display area.

2. Description of Related Art

Liquid crystal display (LCD) apparatus and organic electro luminescence (EL) display apparatus have become increasingly important with the advanced development of a sophisticated information society and the rapid proliferation of multimedia systems. Active matrix system using thin film transistors (TFTs) arranged in an array is widely employed as a driving method of pixels in such display apparatus.

Generally, a TFT is produced by forming an island-shaped silicon on an insulating substrate such as glass and further forming a gate insulating film and a gate electrode on the island-shaped silicon. A capacitor is formed in the same step as forming a TFT circuit.

FIGS. 7 and 8 are a plan view and a sectional view, respectively, of a capacitor portion as a part of a display apparatus according to a related art. As shown in FIGS. 7 and 8, a silicon nitride film 113 and a silicon oxide film 114 are formed as a base layer on an insulating substrate 111. Further, a polycrystalline silicon electrode 118 is formed at a prescribed position on the silicon oxide film 114. A gate insulating film 116 is formed on the polycrystalline silicon electrode 118. Further, a gate metal electrode 117 is formed on the gate insulating film 116 at the position opposite to the polycrystalline silicon electrode 118. The polycrystalline silicon electrode 118 is often used as a conductor by introducing an impurity into a polycrystalline silicon film by ion injection or by ion doping. In such a case, a capacitor is formed with the polycrystalline silicon electrode 118 as one electrode and the gate metal electrode 117 as the other electrode. The edge of the polycrystalline silicon electrode 118 is located outside of the gate metal electrode 117 when viewed from the top.

Because the polycrystalline silicon electrode 118 is larger than the gate metal electrode 117 so that the edge of the polycrystalline silicon electrode 118 is located outside of the edge of the gate metal electrode 117 when viewed from the top, leakage current from the polycrystalline silicon electrode 118 is high, resulting in unstable storage characteristics. This causes disadvantages such as a failure to exhibit suitable circuit performance.

A technique which is intended to reduce such leakage current is disclosed in Japanese Unexamined Patent Application Publication No. 2002-76346 (Watanabe). According to a semiconductor apparatus, its manufacturing method, and an organic EL display panel taught by Watanabe, an island-shaped silicon is covered with a dual-layer thermal oxidation film which is composed of a first thermal oxidation film and a second thermal oxidation film, so that a total film thickness of the dual-layer thermal oxidation film at the edge of the island-shaped silicon is 70% or higher than a total film thickness of the dual-layer thermal oxidation film on the top surface of the island-shaped silicon, thereby reducing leakage current. In this way, the related art addresses the above drawback by forming a thermal oxidation film in a multilayer structure.

However, the technique taught by Watanabe has a drawback of an increase in the manufacturing process for forming a multilayer thermal oxidation film. In light of the foregoing, it is an object of the present invention to provide a display apparatus capable of reducing leakage current from a polycrystalline silicon electrode with a simple structure, and a method of manufacturing the same.

### SUMMARY OF THE INVENTION

In view of the foregoing, according to an aspect of the present invention, there is provided a display apparatus which includes an insulating substrate, a polycrystalline silicon electrode placed above the insulating substrate, a gate insulating film placed on the polycrystalline silicon electrode, and a gate metal electrode placed on the gate insulating film at a position opposite to the polycrystalline silicon electrode, wherein the gate metal electrode partly or entirely covers an edge of the polycrystalline silicon electrode when viewed from a top.

According to another aspect of the present invention, there is provided a method of manufacturing a display apparatus, which includes forming a polycrystalline silicon thin film above a substrate, forming a gate insulating film on the polycrystalline silicon thin film, forming a polycrystalline silicon electrode by implanting a impurity into the polycrystalline silicon film, and forming a gate metal electrode by forming and patterning a conductive film on the gate insulating film, wherein the gate metal electrode is formed to partly or entirely cover an edge of the polycrystalline silicon electrode when viewed from a top.

The present invention can provide a display apparatus capable of reducing leakage current from a polycrystalline silicon electrode with a simple structure to exhibit stable storage characteristics, and a method of manufacturing the same.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a sectional view showing a TFT and a capacitor portion in a typical display apparatus;

FIGS. 2A to 2D are sectional views showing the manufacturing process (up to formation of a gate metal electrode) of a capacitor portion as a part of a display apparatus;

FIG. 3A is a plan view showing a capacitor portion as a part of a display apparatus according to a first embodiment of the invention;

FIG. 3B is a sectional view showing the capacitor portion as a part of the display apparatus according to the first embodiment of the invention;

FIG. 4 is a plan view showing the structure of a capacitor portion in which the corners of a polycrystalline silicon pattern are not covered with a gate metal electrode according to a second embodiment of the invention;

FIG. 5A is a plan view showing the structure of a capacitor portion in which a part of a gate metal electrode has an opening according to a third embodiment of the invention;

FIG. 5B is a sectional view showing the structure of a capacitor portion in which a part of a gate metal electrode has an opening according to the third embodiment of the invention;

FIG. 5C is a sectional view showing the structure of a capacitor portion in which a part of a gate metal electrode has an opening in the state where formation of a wiring layer is finished according to the third embodiment of the invention;

FIG. 6A is a plan view showing the structure of a capacitor portion in which a part of a gate metal electrode has a recess according to the third embodiment of the invention;

FIG. 6B is a sectional view showing the structure of a capacitor portion in which a part of a gate metal electrode has a recess according to the third embodiment of the invention;

FIG. 6C is a sectional view showing the structure of a capacitor portion in which a part of a gate metal electrode has a recess in the state where formation of a passivation film is finished according to the third embodiment of the invention;

FIG. 7 is a plan view showing a capacitor portion as a part of a display apparatus according to a related art; and

FIG. 8 is a sectional view showing the capacitor portion as a part of the display apparatus according to the related art.

### DESCRIPTION OF THE PREFERRED EMBODIMENTS

Exemplary embodiments of the present invention are described hereinafter in detail with reference to the drawings. The following description explains some embodiments of the present invention by way of illustration, and the present invention is not limited to the embodiments described hereinbelow.

### First Embodiment

A first embodiment of the present invention achieves reduction of leakage current by forming an upper electrode of a capacitor in a display apparatus so as to cover the edge of a lower electrode. To begin with, the structure of a typical display apparatus is described. The display apparatus includes a plurality of scan signal lines arranged in parallel on a display area of an insulating substrate and a plurality of display signal lines arranged in parallel to intersect with the scan signal lines. An area surrounded with adjacent scan signal lines and display signal lines serves as a pixel, and a plurality of pixels are arranged in matrix on the display area. Further, a scan signal driver for driving the scan signal lines and a display signal driver for driving the display signal liens are placed on the insulating substrate. At least one thin film transistor (TFT) and capacitor are formed in each pixel.

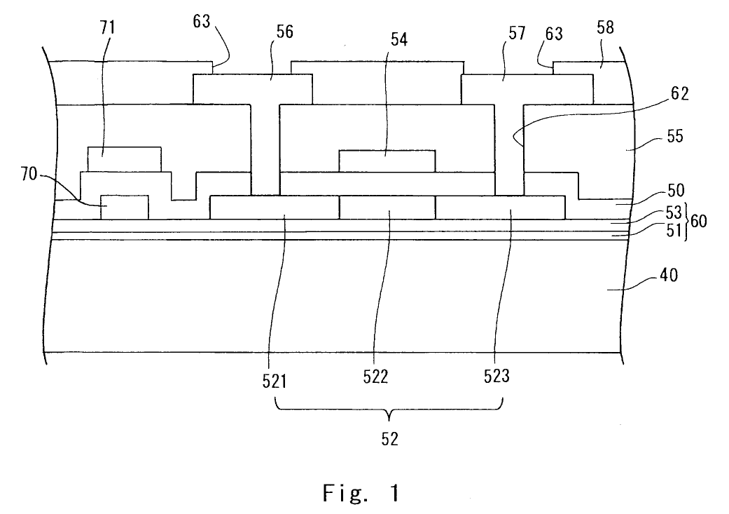

FIG. 1 is a sectional view schematically showing the structure of a TFT and a capacitor. A top-gate structure in which a gate electrode 54 of a TFT is placed above a semiconductor film 52 made of a polycrystalline silicon layer is employed, and a TFT is composed of a p-channel MOSFET. The structure in FIG. 1 includes base layers 51 and 53, the semiconductor film 52, a gate insulating film 50, a gate electrode 54, an interlayer insulating film 55, a source electrode 56, a drain electrode 57, a passivation film 58, a contact hole 62, a capacitor lower electrode 70, and a capacitor upper electrode 71.

A transparent glass substrate or the like may be used as an insulating substrate 40. Alternatively, a metal substrate such as Al or stainless steel may be used. An insulating base layer 60 is formed on the insulating substrate 40. The base layer 60 is formed substantially all over the insulating substrate 40. A silicon nitride film 51 and a silicon oxide film 53, which are transparent insulating films, may be used as the base layer 60. Although the base layer 60 has a multilayer structure in this example, it may be a single layer structure having either one film. The semiconductor film 52 is formed on the base layer 60. The semiconductor film 52 is patterned into an island-shape. Thus, the semiconductor film 52 on the base layer 60 has a rectangular pattern.

The semiconductor film 52 includes a source region 521, a channel region 522, and a drain region 523. The channel region 522 is placed between the source region 521 and the drain region 523. The source region 521 and the drain region 523 are conductive regions containing impurities, and they are placed on both sides of the channel region 522. The channel region 522 is a region where a channel is formed upon application of a gate voltage to the gate electrode. The semiconductor film 52 is made of a polycrystalline silicon film, for example. In the patterning of the semiconductor film 52, the edge of the semiconductor film 52 may be tapered. This ensures that the semiconductor film 52 is covered with the gate insulating film 50, which is described later. It is thereby possible to reduce defects such as dielectric breakdown.

The capacitor lower electrode 70 is formed at a separate position from the semiconductor film 52 or as the same island as the drain region 523. The gate insulating film 50 is formed on the semiconductor film 52. The gate insulating film 50 entirely covers the semiconductor film 52. Thus, the lower surface of the gate insulating film 50 is in contact with the upper surface of the semiconductor film 52. Further, the gate electrode 54 is formed on the gate insulating film 50. The gate electrode 54 is placed above the channel region 522 of the semiconductor film 52. Thus, the gate electrode 54 and the channel region 522 of the semiconductor film 52 are placed opposite to each other with the gate insulating film 50 interposed therebetween. Furthermore, the capacitor upper electrode 71 is formed at a separate position from the gate electrode 54 and opposite to the capacitor lower electrode 70 with the gate insulating film 50 interposed therebetween.

The interlayer insulating film 55 is formed on the gate electrode 54 and the gate insulating film 50. The interlayer insulating film 55 covers the gate electrode 54. The interlayer insulating film 55 and the gate insulating film 50 have the contact holes 62. The contact holes 62 penetrate through the interlayer insulating film 55 and the gate insulating film 50. The contact holes 62 thereby reach the semiconductor film 52.

The source electrode 56 and the drain electrode 57 are respectively filled in the contact holes 62. The source electrode 56 is connected with the source region 521. The drain electrode 57 is connected with the drain region 523.

In this way, the source electrode 56 and the drain electrode 57 extend from the top of the interlayer insulating film 55 to the semiconductor film 52. Thus, the source electrode 56 and the drain electrode 57 are exposed outside on the interlayer insulating film 55. Further, the passivation film 58 is formed on the interlayer insulating film 55 so as to cover the source electrode 56 and the drain electrode 57. The passivation film 58 may have through holes 63 for establishing a connection with the source electrode 56 and the drain electrode 57.

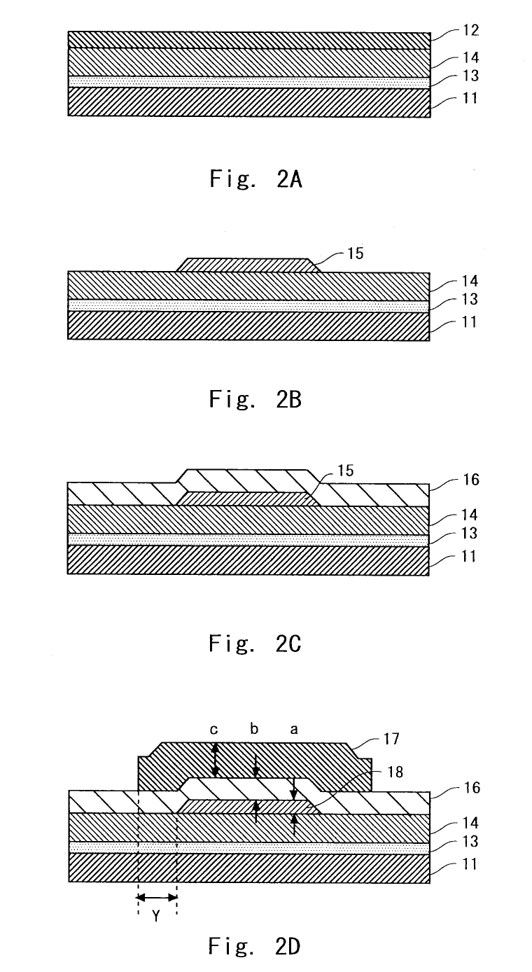

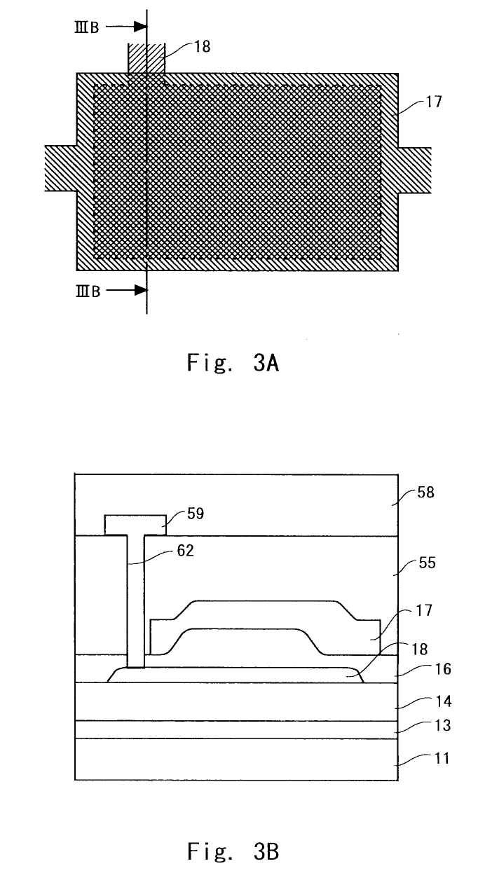

The structure of a capacitor in the display apparatus having such a structure is described hereinafter with reference to FIGS. 2D, 3A and 3B. FIG. 2D is a sectional view of a capacitor portion which is a part of the display apparatus according to the first embodiment of the invention. FIG. 3A is a plan view of the capacitor portion which is a part of the display apparatus of the first embodiment. The structure of FIG. 2D may be applied to a capacitor which is composed of the capacitor lower electrode 70 and the capacitor upper electrode 71. FIG. 3B is a sectional view along line IIIB-IIIB in FIG. 3A, in the state where formation of a passivation film is finished.

As shown in FIG. 2D, a silicon nitride film 13 and a silicon oxide film 14 are formed as a base layer on an insulating substrate 11. Further, a polycrystalline silicon electrode 18 is formed at a prescribed area on the silicon oxide film 14. A gate insulating film 16 is formed on the polycrystalline silicon electrode 18. Further, a gate metal electrode 17 is formed on the gate insulating film 16 at the position opposite to the polycrystalline silicon electrode 18. As shown in FIG. 3A, the edge of the gate metal electrode 17 is located outside of the polycrystalline silicon electrode 18 when viewed from the top. The gate metal electrode 17 corresponds to the capacitor upper electrode 71 shown in FIG. 1, and the polycrystalline silicon electrode 18 corresponds to the capacitor lower electrode 70 shown in FIG. 1. As shown in FIG. 3B, the interlayer insulating film 55 is formed on the gate metal electrode 17. The interlayer insulating film 55 has the contact hole 62 for establishing a connection between a lead wiring portion of the polycrystalline silicon electrode 18 and a wiring layer. The wiring layer 59 is formed on the interlayer insulating film 55, and the passivation film 58 is further formed thereon.

When a distance from the edge of the polycrystalline silicon electrode 18 to the edge of the gate metal electrode 17 is Y, a film thickness of the polycrystalline silicon electrode 18 is a, a film thickness of the gate insulating film 16 is b, and a film thickness of the gate metal electrode 17 is c, it is preferred to satisfy Y≧(a+b+c)/2. This is because, if the distance Y from the edge of the polycrystalline silicon electrode 18 to the edge of the gate metal electrode 17 is equal to or larger than a sum of ½ of a total of each film thickness, the gate metal electrode 17 can sufficiently cover the polycrystalline silicon electrode 18, which enables reduction of leakage current from the polycrystalline silicon electrode 18. Each film thickness preferably satisfies the relationship of c>a, b. Satisfying the relationship of c>a, b allows the edge of the polycrystalline silicon electrode 18 to be covered for sure. The film thickness of the polycrystalline silicon electrode 18 is 50 to 100 nm, for example, under the constraint of the irradiation energy when obtaining polycrystalline silicon from amorphous silicon by laser annealing. The film thickness b of the gate insulating film 16 is 50 to 150 nm, for example, under the constraint of transistor characteristics. The film thickness c of the gate metal electrode 17 is 200 to 400 nm, for example, for ion doping upon forming a source-drain region of a transistor, for use as a self-alignment mask upon ion implantation, and in consideration of a resistance of the gate electrode. The relationship of c>a,b may be satisfied based on those device characteristics, under process constraints and so on.

A method of manufacturing the display apparatus of the first embodiment having such a structure is described hereinafter with reference to FIGS. 2A to 2D. The process up to a gate-metal electrode formation step which is directly related to the first embodiment is described, and the process after the gate-metal electrode formation step is omitted. FIGS. 2A to 2D are sectional views showing each step in the process of manufacturing a capacitor as a part of the display apparatus.

Referring first to FIG. 2A, the silicon nitride film 13 and the silicon oxide film 14 are formed as a base layer on the insulating substrate 11. A glass substrate is generally used as the insulating substrate 11. A quartz glass substrate having a high melting point may be used. The silicon nitride film 13 and the silicon oxide film 14 may be used as the base layer. Either one of the silicon nitride film 13 or the silicon oxide film 14 may be used as a single base layer. Then, an amorphous silicon film 12 with a thickness of 50 to 70 nm is formed on the base layer by plasma CVD.

The amorphous silicon film 12 is molten by excimer laser annealing or the like and then cooled to be hardened, thereby forming a polycrystalline silicon film. After forming a resist pattern on the polycrystalline silicon film by photolithography, the polycrystalline silicon film is patterned into a polycrystalline silicon pattern 15 by dry etching as shown in FIG. 2B. An unnecessary resist is removed. In this step, the pattern of the semiconductor film 52 of FIG. 1 is also formed.

Referring next to FIG. 2C, the gate insulating film 16 is formed on the polycrystalline silicon pattern 15. The gate insulating film 16 may be formed by plasma CVD or the like. After forming the gate insulating film 16, a resist pattern is formed by photolithography. Then, an impurity such as phosphorus is implanted into the polycrystalline silicon pattern 15, which becomes one electrode of a capacitor, by ion injection or ion doping, thereby forming the polycrystalline silicon electrode 18. After the impurity implantation, an unnecessary resist is removed. In this step, an impurity is also implanted in to the semiconductor film 52 of FIG. 1.

Referring then to FIG. 2D, a conductive film is formed on the gate insulating film 16 at the position opposite to the polycrystalline silicon electrode 18. Then, a resist pattern is formed on the conductive film by photolithography, and an unnecessary part of the conductive film is removed by etching, thereby forming the gate metal electrode 17. In this step, the gate electrode 54 of FIG. 1 is also formed.

As described earlier, the gate metal electrode 17, which is one electrode of a capacitor, is in the inner position with respect to the polycrystalline silicon electrode 18, which is the other electrode of the capacitor, when viewed from the top in the display apparatus of the related art. In such a structure, leakage current from the polycrystalline silicon electrode is high, causing unstable storage characteristics.

To avoid this, the edge of the gate metal electrode 17 is placed in the outer position with respect to the edge of the polycrystalline silicon electrode 18 when viewed from the top as shown in FIG. 3A. The gate metal electrode 17 covers the polycrystalline silicon electrode 18 excluding the lead wiring portion thereof. This reduces leakage current from the polycrystalline silicon electrode 18 as one electrode of the capacitor, thus providing stable storage characteristics.

In this embodiment, the edge of the gate metal electrode 17 is located outside of the edge of the polycrystalline silicon electrode 18 when viewed from the top, so that the gate metal electrode 17 covers the polycrystalline silicon electrode 18 excluding the lead wiring portion thereof. It is thereby possible to reduce leakage current from the polycrystalline silicon electrode 18 with a very simple structure. This enables obtainment of stable storage characteristics of a capacitor, thus providing a display apparatus which exhibits stable display characteristics.

### Second Embodiment

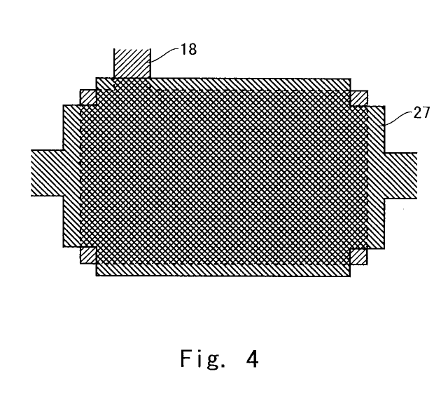

A display apparatus according to a second embodiment of the present invention is described hereinafter with reference to FIG. 4. FIG. 4 is a plan view of the display apparatus according to the second embodiment. In the display apparatus of the second embodiment shown in FIG. 4, the same elements as in the first embodiment shown in FIGS. 2A to 2D are denoted by the same reference numerals and not described in detail herein.

The display apparatus of this embodiment shown FIG. 4 is different from the display apparatus of the first embodiment shown in FIG. 3A in that a gate metal electrode 27 covers the polycrystalline silicon electrode 18 excluding the four corners and the lead wiring portion, rather than excluding the lead wiring portion only. Thus, the four corners and the lead wiring portion of the polycrystalline silicon electrode 18 are not covered with the gate metal electrode 27 in this embodiment.

The manufacturing process of this embodiment is the same as that of the first embodiment up to the step of forming the gate insulating film 16. After forming the gate insulating film 16, the gate metal electrode 27 is formed. The gate metal electrode 27 is formed to have a shape which covers the polycrystalline silicon electrode 18 excluding the four corners.

According to this embodiment, the gate metal electrode 27 covers the polycrystalline silicon electrode 18 excluding the four corners. It is thereby possible to prevent the occurrence of electric field concentration at the corners of the polycrystalline silicon electrode 18, thus avoiding insulation failure. This enables obtainment of stable storage characteristics and insulation characteristics in a display apparatus.

### Third Embodiment

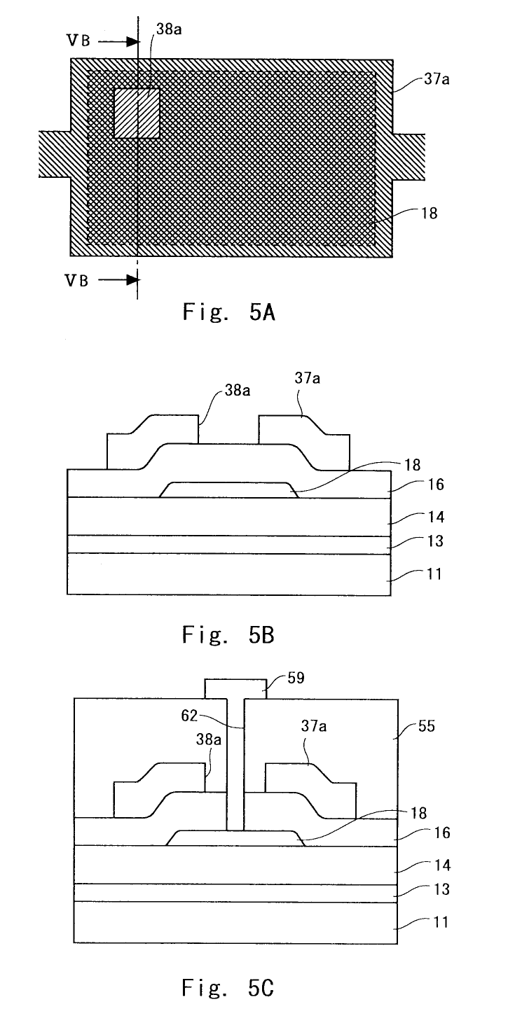

A display apparatus according to a third embodiment of the present invention is described hereinafter with reference to FIGS. 5A to 5C. FIG. 5A is a plan view of the display apparatus according to the third embodiment. FIG. 5B is a sectional view along line VB-VB in FIG. 5A, showing the display apparatus of the third embodiment in the state where the formation of a gate metal electrode is finished. FIG. 5C is a sectional view like FIG. 5B, showing the state where the formation of a wiring layer is finished. In the display apparatus of the third embodiment shown in FIGS. 5A to 5C, the same elements as in the first embodiment shown in FIGS. 2A to 2D are denoted by the same reference numerals and not described in detail herein.

The display apparatus of this embodiment shown FIG. 5A is different from the display apparatus of the first embodiment shown in FIG. 3A in that a gate metal electrode 37a has an opening 38a at which a contact hole for connecting the polycrystalline silicon electrode 18 and the wiring layer is formed, rather than that the gate metal electrode 17 covers the polycrystalline silicon electrode 18 excluding the lead wiring portion.

The manufacturing process of this embodiment is the same as that of the first embodiment up to the step of forming the gate insulating film 16. After that, in the step of forming the gate metal electrode, the opening 38a is formed in a part of the gate metal electrode 37a as shown in FIG. 5B. Then, the interlayer insulating film 55 is formed on the gate metal electrode 37a having the opening 38a as shown in FIG. 5C. After that, the contact hole 62 for establishing a connection between the polycrystalline silicon electrode and the wiring layer is formed in the opening 38a of the gate metal electrode 37a. Further, a wiring layer 59 is formed on the interlayer insulating film 55. The wiring layer 59 is thereby connected with the polycrystalline silicon electrode 18. The wiring layer 59 is formed in the same step as the source electrode 56 and the drain electrode 57 shown in FIG. 1, and it is connected with either one of the source electrode 56 and the drain electrode 57. In such a structure, the edge of the polycrystalline silicon electrode 18 can be entirely covered with the gate metal electrode 37a, which enables reduction of leakage current.

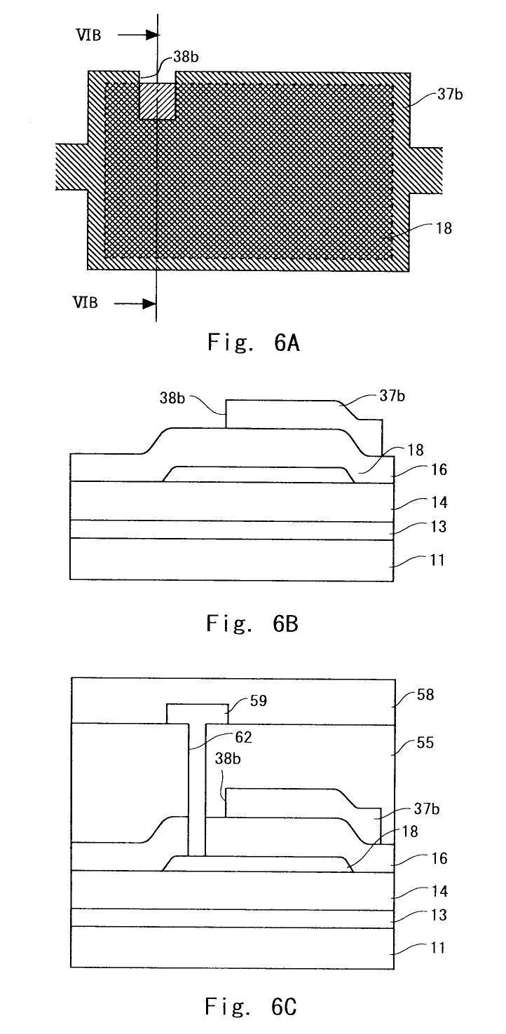

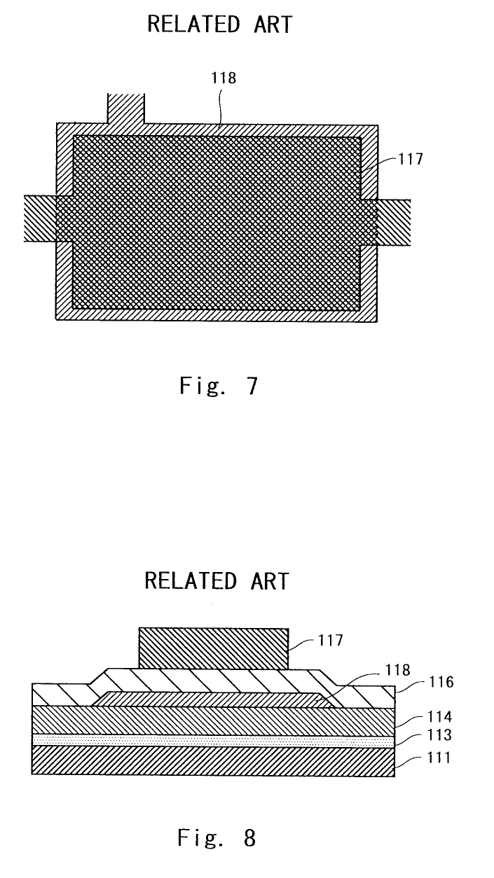

FIGS. 6A to 6C show alternative examples of the display apparatus shown in FIGS. 5A to 5C. FIG. 6A is a plan view of the display apparatus in which an opening is formed at the edge of a gate metal electrode. FIG. 6B is a sectional view along line VIB-VIB in FIG. 6A, showing the display apparatus in which the opening is formed at the edge of the gate metal electrode, in the state where the formation of the gate metal electrode is finished. FIG. 6C is a sectional view like FIG. 6B, showing the display apparatus in the state where the formation of a passivation film is finished.

As shown in FIG. 6A, an opening may be formed at the edge of the gate metal electrode 37b. The manufacturing process of this embodiment is the same as that of the first embodiment up to the step of forming the gate insulating film 16. After that, in the step of forming the gate metal electrode 37b, a recess 38b is formed at the edge of the gate metal electrode 37b as shown in FIG. 6B. Then, the interlayer insulating film 55 is formed on the gate metal electrode 37b having the recess 38b as shown in FIG. 6C. Then, the contact hole 62 for establishing a connection between the polycrystalline silicon electrode and the wiring layer is formed in the recess 38b of the gate metal electrode 37b. Further, the wiring layer 59 is formed on the interlayer insulating film 55. The wiring layer 59 is thereby connected with the polycrystalline silicon electrode 18. The wiring layer 59 is formed in the same step as the source electrode 56 and the drain electrode 57 shown in FIG. 1, and it is connected with either one of the source electrode 56 and the drain electrode 57. After that, the passivation film 58 is formed to cover the wiring layer 59 and the interlayer insulating film 55.

According to this embodiment, an electrical connection between the polycrystalline silicon electrode 18 and the wiring layer is established by forming the opening 38a in a part of the gate metal electrode 37a or by forming the recess 38b in a part of the gate metal electrode 37b, rather than by forming a lead wiring directly from the polycrystalline silicon electrode 18. Further, a contact hole for connecting the polycrystalline silicon electrode 18 and the wiring layer is formed in the opening 38a or the recess 38b. It is thereby possible to obtain a capacitor which enables reduction of leakage current.

A TFT array substrate which includes the capacitor and the TFT described in the first to third embodiments has the advantages of reducing the leakage current from the polycrystalline silicon electrode and providing stable storage characteristics. It is thus suitable for use in a display apparatus. Specifically, it is applicable to a display apparatus which includes an active matrix array substrate having signal lines and scan lines intersecting with each other and a TFT with a capacity located in the vicinity of each intersection.

For example, it is applicable to a liquid crystal display apparatus in which an array substrate and a color filter substrate are attached to each other by a sealing material, with a liquid crystal material interposed therebetween. Further, it is also applicable to an EL display apparatus in which a self-luminous material and a counter electrode are placed on top of a drain electrode or a pixel electrode connected with the drain electrode on an array substrate. Furthermore, it is applicable to not only a TFT in a display area but also a TFT in a driver placed in the vicinity of the display area. In such a case, the TFT in the driver can be formed at the same time as the TFT in the display area.

From the invention thus described, it will be obvious that the embodiments of the invention may be varied in many ways. Such variation are not to be regarded as a departure from the spirit and scope of the invention, and all such modifications as would be obvious to one skilled in the art are intended for inclusion within the scope of the following claims.

What is claimed is:

1. A display apparatus comprising:
an insulating substrate;
a polycrystalline silicon electrode placed above the insulating substrate;
a gate insulating film placed on the polycrystalline silicon electrode; and
a gate metal electrode placed on the gate insulating film at a position opposite to the polycrystalline silicon electrode,
wherein the gate metal electrode partly or entirely covers an edge of the polycrystalline silicon electrode when viewed from a top.

2. The display apparatus according to claim 1, wherein
Y≧(a+b+c)/2 is satisfied where a distance from an edge of the polycrystalline silicon electrode to an edge of the gate metal electrode is Y, a film thickness of the polycrystalline silicon electrode is a, a film thickness of the gate insulating film is b, and a film thickness of the gate metal electrode is c.

3. The display apparatus according to claim 2, wherein
c>a, b is satisfied where a distance from an edge of the polycrystalline silicon electrode to an edge of the gate metal electrode is Y, a film thickness of the polycrystalline silicon electrode is a, a film thickness of the gate insulating film is b, and a film thickness of the gate metal electrode is c.

4. The display apparatus according to claim 1, wherein
the gate metal electrode covers the edge of the polycrystalline silicon electrode excluding a lead wiring portion of the polycrystalline silicon electrode.

5. The display apparatus according to claim 4, wherein
Y≧(a+b+c)/2 is satisfied where a distance from an edge of the polycrystalline silicon electrode to an edge of the gate metal electrode is Y, a film thickness of the polycrystalline silicon electrode is a, a film thickness of the gate insulating film is b, and a film thickness of the gate metal electrode is c.

6. The display apparatus according to claim 1, wherein
the gate metal electrode covers the edge of the polycrystalline silicon electrode excluding four corners of the polycrystalline silicon electrode.

7. The display apparatus according to claim 6, wherein
Y≧(a+b+c)/2 is satisfied where a distance from an edge of the polycrystalline silicon electrode to an edge of the gate metal electrode is Y, a film thickness of the polycrystalline silicon electrode is a, a film thickness of the gate insulating film is b, and a film thickness of the gate metal electrode is c.

8. The display apparatus according to claim 1, wherein
the gate metal electrode has an opening, and
a contact hole connecting between the polycrystalline silicon electrode and a wiring layer is formed in the opening.

9. The display apparatus according to claim 8, wherein
Y≧(a+b+c)/2 is satisfied where a distance from an edge of the polycrystalline silicon electrode to an edge of the gate metal electrode is Y, a film thickness of the polycrystalline silicon electrode is a, a film thickness of the gate insulating film is b, and a film thickness of the gate metal electrode is c.

10. The display apparatus according to claim 1, further comprising:
a base layer placed between the insulating substrate and the polycrystalline silicon electrode.

11. A method of manufacturing a display apparatus, comprising:
forming a polycrystalline silicon thin film above a substrate;
forming a gate insulating film on the polycrystalline silicon thin film;
forming a polycrystalline silicon electrode by implanting a impurity into the polycrystalline silicon film; and
forming a gate metal electrode by forming and patterning a conductive film on the gate insulating film,
wherein the gate metal electrode is formed to partly or entirely cover an edge of the polycrystalline silicon electrode when viewed from a top.

12. The method of manufacturing a display apparatus according to claim 11, wherein
the gate metal electrode is formed to cover the edge of the polycrystalline silicon electrode excluding a lead wiring portion of the polycrystalline silicon electrode.

13. The method of manufacturing a display apparatus according to claim 11, wherein
the gate metal electrode is formed to cover the edge of the polycrystalline silicon electrode excluding four corners of the polycrystalline silicon electrode.

14. The method of manufacturing a display apparatus according to claim 11, further comprising:
forming an opening in a part of the gate metal electrode; and
forming a contact hole connecting between the gate metal electrode and the polycrystalline silicon electrode in the opening.
